(19) United States
(12) Patent Application Publication
(10) Pub. No.: US 2008/0073745 A1
(43) Pub. Date: Mar. 27, 2008

(54) High-voltage MOS device improvement by forming implantation regions

(76) Inventors: Chien-Shao Tang, Hsinchu City (TW); Tsung-Yi Huang, Hsin-Chu (TW); David Ho, Taichung City (TW); Zhe-Yi Wang, Hsinchu City (TW); Yu-Chang Jong, Hsinchu City (TW)

Correspondence Address: SLATER & MATSIL, L.L.P., 17950 PRESTON ROAD, SUITE 1000, DALLAS, TX, 75252, US

(21) Appl. No.: 11/526,419

(22) Filed: Sep. 25, 2006

(51) Int. Cl. H01L 29/00

(52) U.S. Cl. 257/500

(57) ABSTRACT

A high-voltage semiconductor structure includes a high-voltage well region overlying a substrate, an isolation region extending from a top surface of the high-voltage well region into the high-voltage well region, a low-voltage well region having at least a portion underlying and adjoining the isolation region wherein the low-voltage well region is inside of and of a same conductivity type as the high-voltage well region, a gate dielectric on the high-voltage well region, a gate electrode on the gate dielectric, and a source/drain region of the same conductivity type as the high-voltage well region, wherein the source/drain region is spaced apart from a channel region by the isolation region.

### TECHNICAL FIELD

This invention relates generally to semiconductor devices, and more particularly to metal-oxide-semiconductor (MOS) devices, and even more particularly to the structure and manufacturing methods of high-voltage MOS devices.

### BACKGROUND

High-voltage metal-oxide-semiconductor (HVMOS) devices are widely used in many electrical devices, such as CPU power supplies, power management systems, AC/DC converters, etc.

FIG. 1 illustrates a conventional HVMOS 2, which includes a gate oxide 10, a gate electrode 12 on gate oxide 10, a drain region 4 in a high-voltage n-well (HVNW) region, and a source region 6 in a high-voltage p-well (HVPW) region. A shallow trench isolation (STI) region 8 spaces the drain region 4 and gate electrode 12 apart so that a high drain-to-gate voltage can be applied.

Breakdown voltage and on-resistance are two of the key parameters of HVMOS devices. Increasing breakdown voltage and lowering on-resistance without an additional mask layer are major issues in the design of HVMOS devices. Typically, the breakdown voltage of an HVMOS device is related to the size of the MOS device, and a high breakdown voltage often requires a great chip area. In addition, greater sized MOS devices mean greater power consumption. Therefore, increasing breakdown voltage by enlarging the size of the MOS device is not a desirable design approach.

What is needed in the art is a high voltage MOS device having a high breakdown voltage without the expense of a great chip area.

### SUMMARY OF THE INVENTION

In accordance with one aspect of the present invention, a high-voltage semiconductor structure includes a high-voltage well region overlying a substrate, an isolation region extending from a top surface of the high-voltage well region into the high-voltage well region, a low-voltage well region having at least a portion underlying and adjoining the isolation region wherein the low-voltage well region is inside of and of a same conductivity type as the high-voltage well region, a gate dielectric on the high-voltage well region, a gate electrode on the gate dielectric, and a source/drain region of the same conductivity type as the high-voltage well region, wherein the source/drain region is spaced apart from a channel region by the isolation region.

In accordance with yet another aspect of the present invention, a semiconductor structure includes a substrate comprising a high voltage (HV) region and a low-voltage (LV) region, a first high-voltage well region in the HV region wherein the first high-voltage well region is doped with an impurity of a first conductivity type, a second high-voltage well region in the HV region and adjoining the first high-voltage well region wherein the second high-voltage well region is doped with an impurity of a second conductivity type opposite the first conductivity type, a gate dielectric on a portion of the first high-voltage well region and extending onto at least a portion of the second high-voltage well region, a gate electrode on the gate dielectric, a source/drain region of the first conductivity type in the first high-voltage well region, an isolation region extending from a top surface of the first high-voltage well region into the first high-voltage well region wherein the gate dielectric and the source/drain region are spaced apart by the isolation region, a first low-voltage well region extending from a bottom surface of the isolation region into the first high-voltage well region wherein the first low-voltage well region is of the first conductivity type and wherein the first low-voltage region has a depth smaller than a depth of the first high-voltage well region, and a second low-voltage well region in the LV region wherein the first and second low-voltage well regions have a substantially same depth.

In accordance with yet another aspect of the present invention, a method for forming a semiconductor structure includes providing a substrate, forming a first high-voltage well region of a first conductivity type overlying the substrate, forming a low-voltage well region wherein the low-voltage well region is inside of the fast high-voltage well region and of a same conductivity type as the first high-voltage well region, forming an isolation region in the first high-voltage well region, wherein the low-voltage well region has at least a portion on the isolation region, forming a gate dielectric on the first high-voltage well region, forming a gate electrode on the gate dielectric, and forming a source/drain region of the first conductivity type in the first high-voltage well region, wherein the source/drain region is spaced apart from a channel region by the isolation region.

In accordance with yet another aspect of the present invention, a method for forming a semiconductor structure includes providing a substrate, forming a first high-voltage well region doped with an impurity of a first conductivity type overlying the substrate, forming a second high-voltage well region doped with an impurity of a second conductivity type opposite the first conductivity type overlying the substrate and adjoining the first high-voltage well region, simultaneously forming a first low-voltage well region in the first high-voltage well region and a second low-voltage well region outside a high-voltage well region, wherein the first and the second low-voltage well regions are of the first conductivity type, and wherein the low-voltage region has a depth smaller than a depth of the first high-voltage well region, forming an isolation region extending from a top surface of the first high-voltage well region into the first high-voltage well region, wherein the isolation region has at least a portion overlapping the low-voltage well region, and wherein the isolation region is shallower than the low-voltage well region, forming a gate dielectric on the first and the second high-voltage well regions and a portion of the isolation region, forming a gate electrode on the gate dielectric, forming a drain region of the first conductivity type in the first high-voltage well region and adjacent the isolation region, and forming a source region of the first conductivity type in a high-voltage well region and on an opposite side of the gate dielectric than the drain region.

The advantageous features of the present invention include increased breakdown voltage, reduced on-state resistance, and reduced power consumption.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional high-voltage NMOS device;

FIGS. 2 through 8 are cross-sectional views of intermediate stages in the manufacture of a high-voltage NMOS device, which has an asymmetric design;

FIG. 9 illustrates simulated I_{d}-V_{d} curves of high voltage devices;

FIG. 10 illustrates a cross-sectional view of an exemplary symmetric high-voltage NMOS device; and

FIG. 11 illustrates a cross-sectional view of an exemplary high-voltage PMOS device.

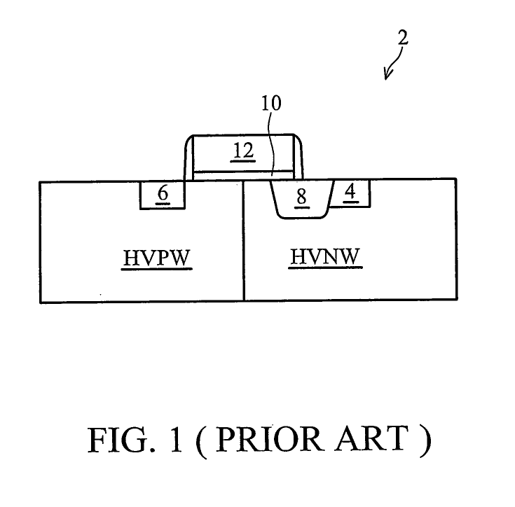

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

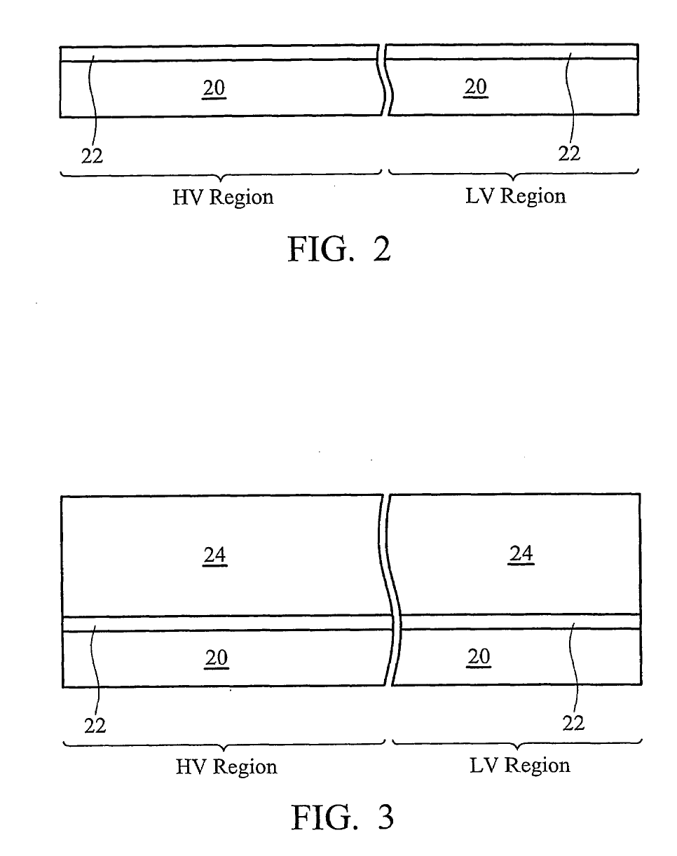

The preferred embodiments of the present invention are described with reference to FIGS. 2 through 8. Variations of the preferred embodiments are then discussed. Throughout the various views and illustrative embodiments of the present invention, like reference numbers are used to designate like elements.

Referring to FIG. 2, a substrate 20 is provided, which preferably comprises a semiconductor material such as silicon, although other semiconductor materials may be used. Substrate 20 is preferably of p-type. Alternatively, it may be doped with n-type impurities. Substrate 20 includes two regions, a high-voltage device region (HV region) and a low-voltage device region (LV region). High-voltage devices are formed in the HV region. Low-voltage devices are formed in the LV region.

Optionally, an N+ buried layer (NBL) 22 is formed in a top region of the substrate 20 proximate the top surface of substrate 20. NBL 22 is preferably formed by implanting dopants into the top surface of the substrate 20. For example, antimony and/or arsenic may be implanted to an impurity concentration of about 10¹⁶/cm³ to about 10¹⁸/cm³. The dopant of the NBL 22 may then be driven into a top region of substrate 20 by heating the substrate 20. In alternative embodiments, if substrate 20 is of n-type, a P+ buried layer will be formed instead. NBL 22 acts as an electrical isolation region, isolating the devices subsequently formed over NBL 22 from substrate 20.

FIG. 3 illustrates a doped semiconductor layer 24 formed over NBL 22. The doped semiconductor layer 24 preferably comprises a semiconductor such as silicon, and is preferably doped with a p-type impurity. The doped semiconductor layer 24 is preferably epitaxially grown, and is alternatively referred to as P-epi layer 24, although other deposition methods may alternatively be used. While epitaxially growing the semiconductor material for layer 24, p-type dopants such as boron are introduced, preferably to a concentration of between about 10¹⁵/cm³ to 10¹⁶/cm³.

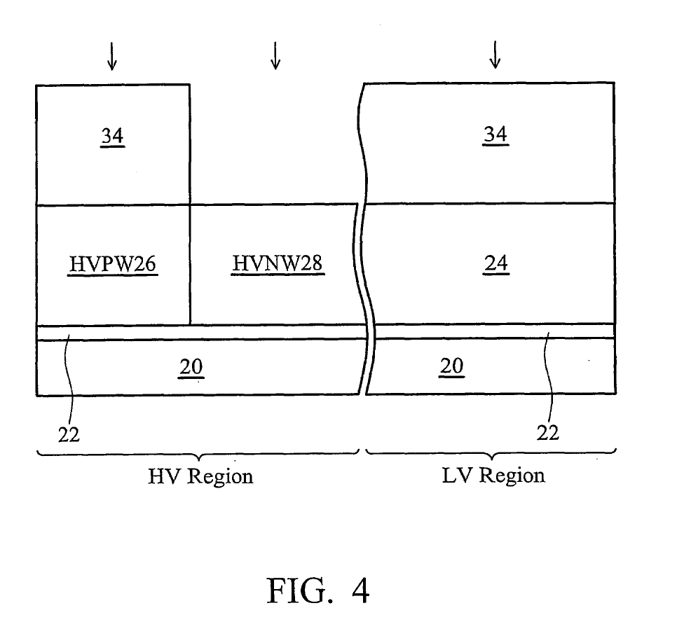

A photo resist 34 is then formed, as is shown in FIG. 4. The photo resist 34 is patterned using lithography techniques. An n-type impurity implantation is then performed in order to form an N-well region 28, also equally referred to as high-voltage n-well (HVNW) region 28, in the HV region. HVNW region 28 preferably comprises antimony and/or arsenic, which neutralizes the p-type impurities in the P-epi layer 24 and converts the implanted region to n-type. After the implanting, HVNW region 28 preferably has a net n-type impurity concentration of between about 10¹⁵/cm³ and about 10¹⁶/cm³. The bottom of HVNW region 28 preferably reaches NBL 22, although a shallower HVNW region 28 may be formed. Due to the masking by the photo resist 34, a portion of the P-epi layer 24 that is masked forms a p-well region 26, which is equally referred to as a high-voltage p-well (HVPW) region 26. Preferably, the LV region is not doped. Photo resist 34 is then removed.

In alternative embodiments, the doped semiconductor layer 24 can be of n-type. By masking a portion of the doped semiconductor layer 24 and doping with p-type impurities, HVPW region 26 and HVNW region 28 can be formed.

In yet alternative embodiments, the doped semiconductor layer 24 is substantially intrinsic. Two masks (not shown) are formed, each masking a portion of the doped semiconductor layer 24 in the HV region. HVPW region 26 and HVNW region 28 are formed by the respective implantations.

In yet alternative embodiments, no NBL 22 is formed. HVPW region 26 and HVNW region 28 are thus formed by directly implanting n-type and p-type impurities into substrate 20.

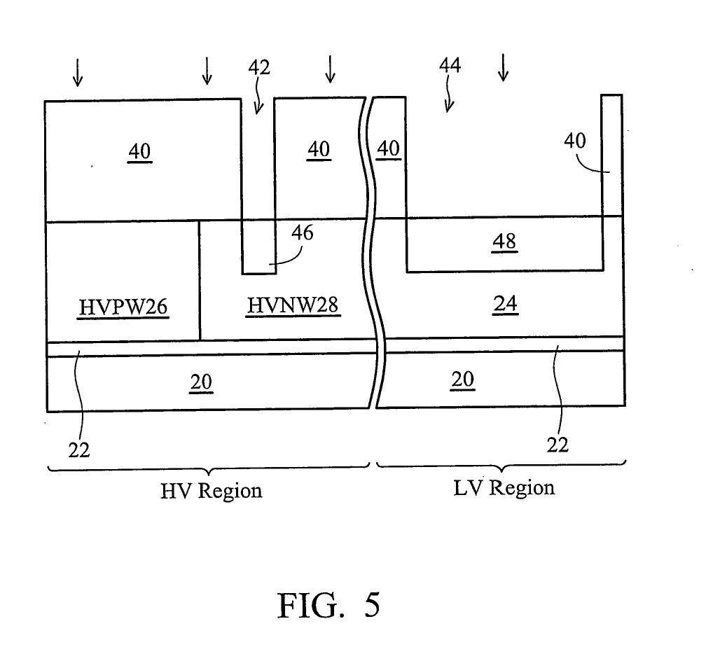

Referring to FIG. 5, low voltage N-wells are formed. A photo resist 40 is formed with openings 42 and 44. Opening 42 is over the HV region, while opening 44 is over the LV region. An n-type impurity implantation is then performed in order to form low voltage N-well (LVNW) regions 46 in the HV region and LVNW region 48 in the LV region. After the implanting, LVNW regions 46 and 48 preferably have a net n-type impurity concentration of between about 1×10⁷/cm³/cm³ and about 1×10¹⁸/cm³. Preferably, LVNW regions 46 and 48 have an impurity concentration higher than the impurity concentration of high voltage regions 26 and 28, and more preferably higher than about one order or greater. The depth of LVNW regions 46 and 48 is preferably less than the depth of the HVNW 28, and thus LVNW region 46 is within HVNW region 28. Photo resist 40 is then removed. In the LV region, LVNW region 48 is for forming low-voltage p-type MOS devices, and thus the impurity elements and the respective concentration of LVNW regions 46 and 48 are preferably determined according to the specifications for forming low-voltage PMOS devices. Alternatively, LVNW regions 46 and 48 are formed in separate process steps.

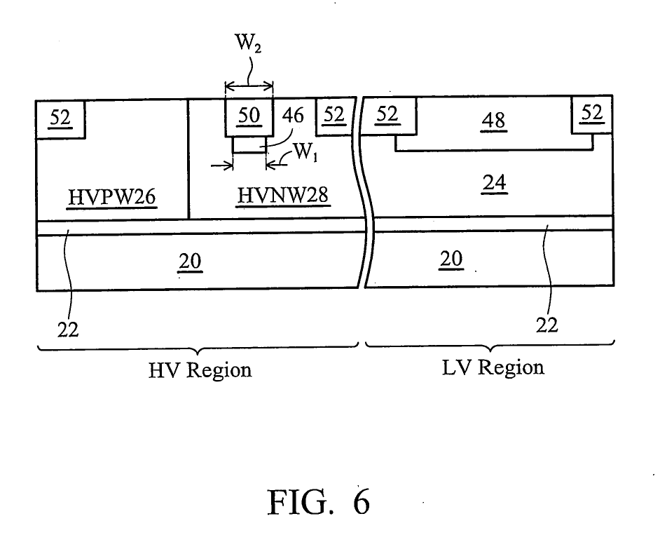

FIG. 6 illustrates the formation of isolation regions 50 and 52. In the preferred embodiment, isolation regions 50 and 52 are shallow trench isolation (STI) regions, and are formed by forming trenches in the HVPW region 26, filling the trenches with a dielectric material, such as SiO₂ or HDP oxide, and performing a chemical mechanical polish to level the surface. In other embodiments, a mask layer is blanket formed. The mask layer is then patterned to form openings at respective positions over isolation regions 50 and 52. An oxidation is then performed, and the field regions (also referred to as field oxides) 50 and 52 are formed through the openings. LVNW region 46 preferably, although not necessarily, has a width W₁ greater than about 25 percent, and more preferably between about 25 percent and about 75 percent of a width W₂ of the STI region 50.

In the previously discussed process steps, the formation of LVNW regions 46 and 48, HVPW region 26, HVNW region 28 and isolation regions 50 and 52 can be performed in different orders than described. For example, HVPW region 26 and HVNW region 28 may be formed prior to the formation of LVNW regions 46 and 48. LVNW regions 46 and 48 can also be formed after the formation of isolation regions 50 and 52.

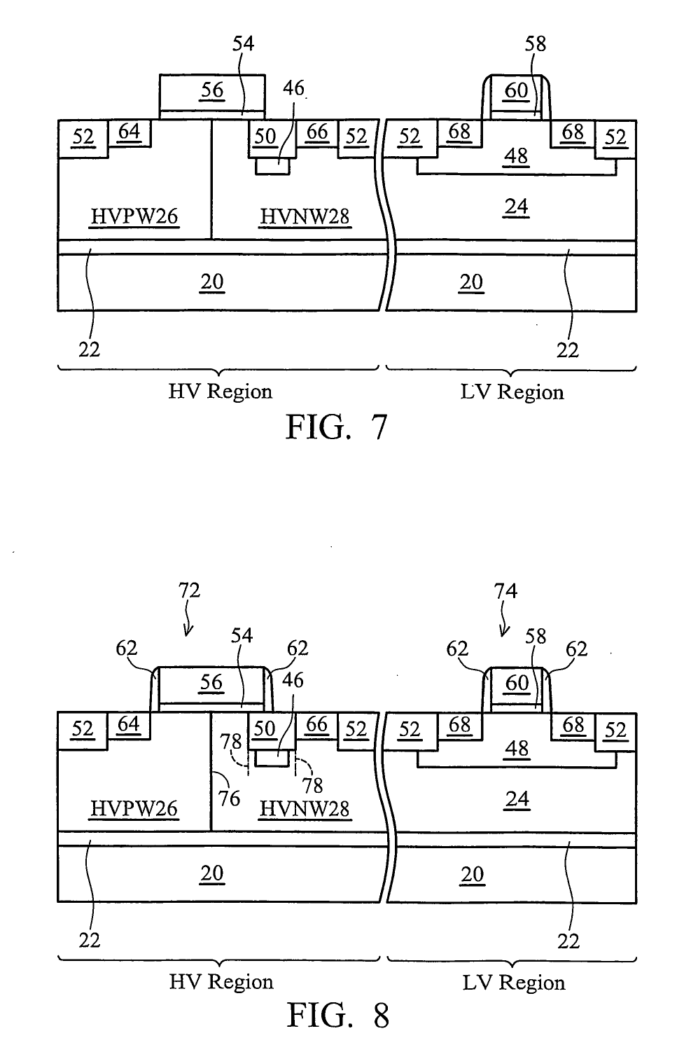

Referring to FIG. 7, a gate stack including a gate dielectric 54 and a gate electrode 56 is formed in the HV region. Preferably, gate dielectric 54 is formed of silicon oxide and gate electrode 56 is formed of polysilicon, although other materials commonly used for high-voltage gate stacks can also be used. Gate dielectric 54 preferably, but not necessarily, has a portion overlying STI region 50. In the LV region, a gate stack including a gate dielectric 58 and a gate electrode 60 is formed. As is known in the art, gate dielectric 58 may be formed of oxides, nitrides, high-k dielectric materials, and the like. Gate electrode 60 may be formed of polysilicon, metals, metal silicides, and combinations thereof. The formation of the gate stacks are well known in the art, thus the steps are not repeated herein.

FIG. 8 illustrates the formation of spacers 62 and source/drain regions 64, 66 and 68. As is known in the art, spacers 62 are preferably formed by depositing a dielectric layer and etching undesired portions. Spacers 62 may comprise a single layer, or have a composite structure with, for example, a nitride-on-oxide structure or an oxide-nitride-oxide (ONO) structure. Source region 64 and drain region 66 are N+ regions formed by implanting n-type impurities. Source/drain regions 68 of the low-voltage MOS device are P+ regions implanted with p-type impurities. Additionally, lightly doped source/drain (LDD) regions and pocket regions (not shown) may be formed in the LV region. The formation processes are well-known in the art, thus are not repeated herein.

The previously performed process steps result in a high-voltage n-type MOS (HVNMOS) device 72 in the HV region and a low-voltage p-type MOS (LVPMOS) device 74 in the LV region. HVNMOS device 72 has an improved breakdown voltage. Simulation results have revealed that the formation of LVNW 46 has caused the redistribution of electrical fields between source 64 and drain 66. The highest electrical field value is lower when compared to HVNMOS devices having no LVNW region 46, although electrical fields are increased in some regions that previously had lower electrical fields. It is commonly understood that the region having the highest electrical field is most likely to break down first, which in turn causes the electrical breakdown of the entire device. Therefore, it is desirable to evenly distribute the electrical fields as much as possible. In the preferred embodiment, LVNW region 46 is simultaneously formed with the LVNW region 48, and thus no extra cost is introduced.

The position of LVNW region 46 may be shifted between drain region 66 and a junction 76, which is between HVNW region 28 and HVPW region 26. More preferably, LVNW region 46 is inside the region defined by the alignment lines 78, which are aligned to edges of the STI regions 50. One skilled in the art will be able to determine the optimum size and position through routine experiments.

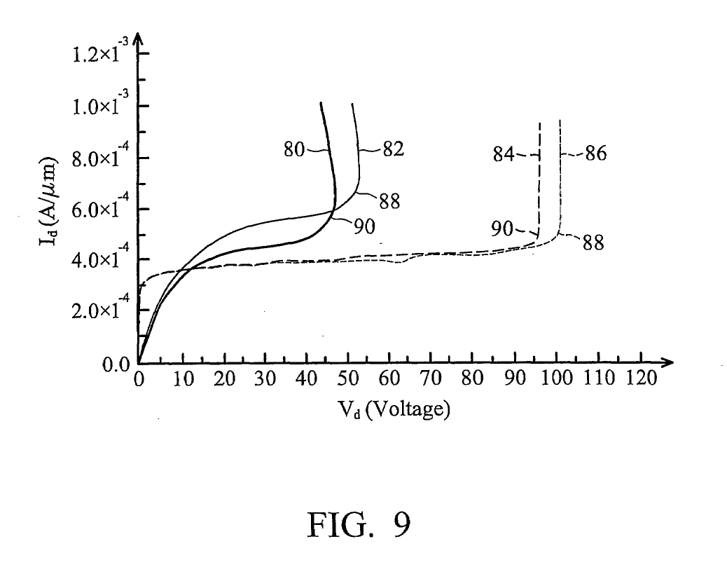

FIG. 9 illustrates simulated I_{d}-V_{d} characteristics of the MOS devices. Lines 80 and 84 represent results obtained from a device having no LVNW region 46, while lines 82 and 86 represent results obtained from a device having a LVNW region 46. Solid lines are obtained at a drain voltage of 40V and a gate voltage of 40V (thus the devices are on), and dashed lines are obtained at a drain voltage of 40V and a gate voltage of 0V (thus the devices are off). It can be found that the breakdown points (88) of a device having an LVNW region appear at greater drain voltages than breakdown points (90) of the device having no LVNW region. In addition, the power consumption of devices having an LVNW region is lower than for devices having no LVNW regions due to lower on-state resistance Rₒₙ.

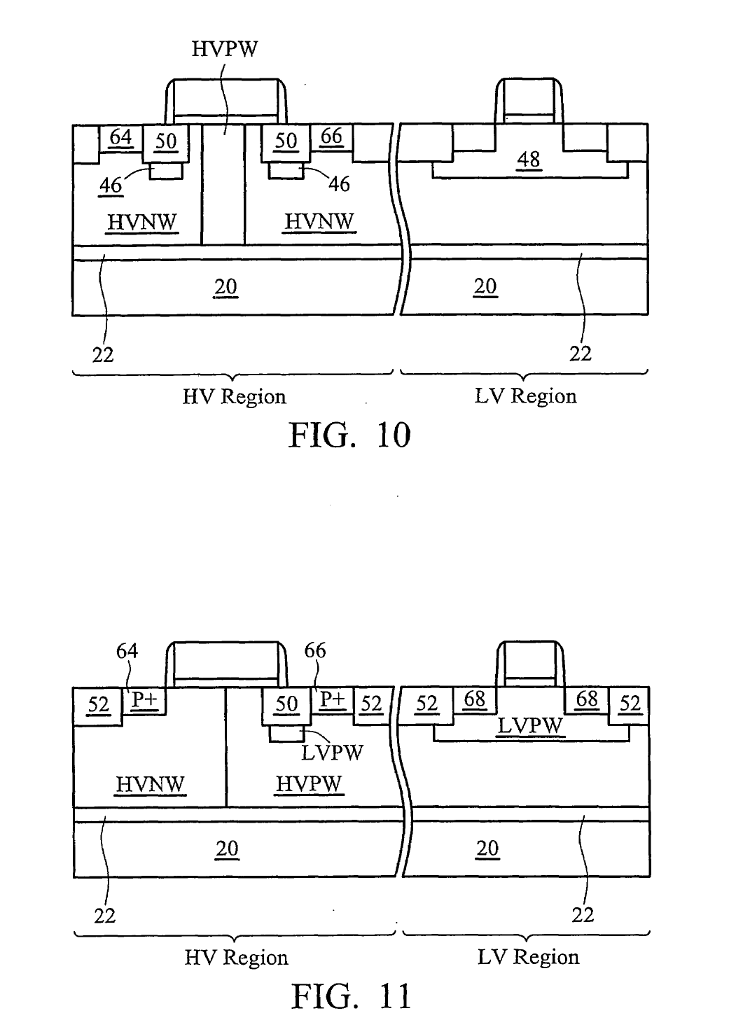

The previously illustrated embodiments have asymmetric structures, wherein source and drain regions are in different types of high-voltage well regions. FIG. 10 illustrates an embodiment having a symmetric structure, wherein the HVNMOS device has two HVNW regions and an HVPW region therebetween. LVNW regions 46 are preferably formed on both source and drain sides. Preferably, LVNW regions 46 are formed simultaneously with the formation of LVNW regions for forming low voltage MOS devices. Alternatively, only one of the LVNW regions 46 is formed, preferably on the drain side. In further embodiments, an LVNW region 46 and the overlying isolation region on one of the source/drain sides are not formed.

Although the preferred embodiments illustrate the formation of an HVNMOS device, one skilled in the art will realize the respective formation steps for forming HVPMOS devices, with the conductivity type of LVNW region 46, HVNW region 28, HVPW region 26 and source/drain regions 64, 66 and 68, etc., reversed. An exemplary illustrative embodiment is shown in FIG. 11. It should also be appreciated that HVMOS devices have various different layouts. However, the concept of forming low voltage well regions, preferably simultaneously with the formation of well regions, for low-voltage MOS devices may also be applied.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A high-voltage semiconductor structure comprising:
a substrate;
a first high-voltage well region of a first conductivity type overlying the substrate;
an isolation region extending from a top surface of the first high-voltage well region into the first high-voltage well region;
a low-voltage well region having at least a portion underlying and adjoining the isolation region, wherein the low-voltage well region is inside of and of a same conductivity type as the first high-voltage well region;
a gate dielectric on the first high-voltage well region;
a gate electrode on the gate dielectric; and
a source/drain region of the first conductivity type in the first high-voltage well region, wherein the source/drain region is spaced apart from a channel region by the isolation region.

2. The semiconductor structure of claim 1, wherein the first conductivity type is p-type.

3. The semiconductor structure of claim 1, wherein the first conductivity type is n-type.

4. The semiconductor structure of claim 1 further comprising an additional low-voltage well region overlying the substrate and outside the first high-voltage well region, wherein the additional low-voltage well region has a same depth as the low-voltage well region.

5. The semiconductor structure of claim 4 further comprising a low-voltage MOS device in the additional low-voltage well region.

6. The semiconductor structure of claim 1 further comprising:
a second high-voltage well region over the substrate, wherein the second high-voltage well region is of the first conductivity type; and
a third high-voltage well region of a second conductivity type opposite the first conductivity type between the first and the second high-voltage well regions, wherein the gate dielectric further extends on portions of the second and third high-voltage well regions.

7. The semiconductor structure of claim 1 further comprising a buried layer of the first conductivity type overlying the substrate and underlying the first high-voltage well region.

8. The semiconductor structure of claim 1, wherein the low-voltage well region is substantially within alignment lines of the isolation region.

9. The semiconductor structure of claim 1 further comprising an additional source/drain region on an opposite side of the gate dielectric than the source/drain region.

10. The semiconductor structure of claim 9 further comprising an additional isolation region separating the gate dielectric and the additional source/drain region, and an additional low-voltage region underlying and adjoining the additional isolation region.

11. A semiconductor structure comprising:
a substrate comprising a high-voltage (HV) region and a low-voltage (LV) region;
a first high-voltage well region in the HV region, wherein the first high-voltage well region is doped with an impurity of a first conductivity type;
a second high-voltage well region in the HV region and adjoining the first high-voltage well region, wherein the second high-voltage well region is doped with an impurity of a second conductivity type opposite the first conductivity type;
a gate dielectric on a portion of the first high-voltage well region and extending on at least a portion of the second high-voltage well region;
a gate electrode on the gate dielectric;
a source/drain region of the first conductivity type in the first high-voltage well region;
an isolation region extending from a top surface of the first high-voltage well region into the first high-voltage well region, wherein the gate dielectric and the source/drain region are spaced apart by the isolation region;
a first low-voltage well region extending from a bottom surface of the isolation region into the first high-voltage well region, wherein the first low-voltage well region is of the first conductivity type, and wherein the first low-voltage region has a depth smaller than a depth of the first high-voltage well region; and
a second low-voltage well region in the LV region, wherein the first and second low-voltage well regions have a substantially same depth.

12. The semiconductor structure of claim 11 further comprising a low-voltage MOS device in the second low-voltage well region.

13. The semiconductor structure of claim 11, wherein the first conductivity type is n-type and the second conductivity type is p-type.

14. The semiconductor structure of claim 11, wherein the first conductivity type is p-type and the second conductivity type is n-type.

15. The semiconductor structure of claim 11, wherein the isolation region is a shallow trench isolation region.

16. The semiconductor structure of claim 11, wherein the first low-voltage well region has a width of between about 25 percent and about 75 percent of a width of the isolation region.

17. The semiconductor structure of claim 11, wherein the first low-voltage well region has a concentration at least about one order greater than a concentration of each of the first and second high-voltage well regions.

18. The semiconductor structure of claim 11 further comprising a third high-voltage well region of the first conductivity type adjacent the second high-voltage well region, wherein the gate dielectric further extends on a portion of the third high-voltage well region.

19. A method for forming a semiconductor structure, the method comprising:
providing a substrate;
forming a first high-voltage well region of a first conductivity type overlying the substrate;
forming a low-voltage well region, wherein the low-voltage well region is inside of the first high-voltage well region and of a same conductivity type as the first high-voltage well region;
forming an isolation region in the first high-voltage well region, wherein the isolation region has at least a portion on the low-voltage well region;
forming a gate dielectric on the first high-voltage well region;
forming a gate electrode on the gate dielectric; and
forming a source/drain region of the first conductivity type in the first high-voltage well region, wherein the source/drain region is spaced apart from a channel region by the isolation region.

20. The method of claim 19 further comprising forming an additional low-voltage well region overlying the substrate and outside the first high-voltage well region, wherein the additional low-voltage well region and the low-voltage well region are simultaneously formed.

21. The method of claim 20 further comprising forming a low-voltage MOS device in the additional low-voltage well region.

22. The method of claim 19 further comprising:
forming a second high-voltage region over the substrate simultaneously with the formation of the first high-voltage well region; and
forming a third high-voltage well region of a second conductivity type opposite the first conductivity type between the first and the second high-voltage well regions, wherein the gate dielectric further extends on portions of the second and third high-voltage well regions.

23. The method of claim 19, wherein the step of forming the isolation region comprises forming a shallow trench isolation region.

24. The method of claim 19, wherein the step of forming the isolation region comprises forming a field oxide region.

25. The method of claim 19 further comprising forming an additional source/drain region on an opposite side of the gate dielectric than the source/drain region.

26. The method of claim 25 further comprising forming an additional isolation region separating the gate dielectric and the additional source/drain region, and an additional low-voltage region underlying and adjoining the additional isolation region.

27. A method for forming a semiconductor structure, the method comprising:
providing a substrate;
forming a first high-voltage well region, doped with an impurity of a first conductivity type, overlying the substrate;
forming a second high-voltage well region, doped with an impurity of a second conductivity type opposite the first conductivity type, overlying the substrate and adjoining the first high-voltage well region;
simultaneously forming a first low-voltage well region in the first high-voltage well region and a second low-voltage well region outside a high-voltage well region, wherein the first and the second low-voltage well regions are of the first conductivity type, and wherein the low-voltage region has a depth smaller than a depth of the first high-voltage well region;
forming an isolation region extending from a top surface of the first high-voltage well region into the first high-voltage well region, wherein the isolation region has at least a portion overlapping the low-voltage well region, and wherein the isolation region is shallower than the low-voltage well region;
forming a gate dielectric on the first and the second high-voltage well regions and a portion of the isolation region;
forming a gate electrode on the gate dielectric;
forming a drain region of the first conductivity type in the first high-voltage well region and adjacent the isolation region; and
forming a source region of the first conductivity type in a high-voltage well region and on an opposite side of the gate dielectric from the drain region.

28. The method of claim 27 further comprising forming a low-voltage MOS device in the second low-voltage well region.

29. The method of claim 27, wherein the steps of forming the first and the second high-voltage well regions comprise epitaxially growing a semiconductor layer over the substrate, and implanting the first and second high-voltage well regions.

30. The method of claim 27, wherein the steps of forming the first and second high-voltage well regions comprise directly implanting the substrate to form the first and second high-voltage well regions.

31. The method of claim 27 further comprising forming a third high-voltage well region of the first conductivity type adjacent the second high-voltage well region and opposite the first high-voltage well region, wherein the gate dielectric further extends on a portion of the third high-voltage well region.
